(19) United States
(12) Patent Application Publication
(10) Pub. No.: US 2005/0173749 A1
(43) Pub. Date: Aug. 11, 2005

(54) Trench capacitor with insulating collar, and appropriate method of fabrication

(75) Inventor: Harald Seidl, Poering (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 11/049,295

(22) Filed: Feb. 3, 2005

(30) Foreign Application Priority Data
Feb. 5, 2004 (DE) 102004005694.3

(51) Int. Cl. H01L 21/8242; H01L 27/108; H01L 29/76; H01L 31/119

(52) U.S. Cl. 257/301; 257/310; 438/386; 438/240

(57) ABSTRACT

The present invention provides a trench capacitor, particularly for use in a semiconductor memory cell, having a trench which is formed in a semiconductor substrate; a first conductive capacitor plate which is situated in and/or next to the trench; a second conductive capacitor plate which is situated in the trench; a dielectric layer, which is situated between the first and second capacitor plates, as capacitor dielectric; and an insulating collar in the upper region of the trench. At least one layer of the first first conductive capacitor plate and/or of the second conductive capacitor plate is made of a material from the class containing the metal borides, metal phosphides and metal antimonides of the transition metals from the secondary groups IV, V and VI of the periodic table.

### CLAIM FOR PRIORITY

This application claims the benefit of priority to German Application No. 10 2004 005 694.3 which was filed in the German language on Feb. 5, 2004, the contents of which are hereby incorporated by reference.

### TECHNICAL FIELD OF THE INVENTION

The present invention relates to a trench capacitor, particularly for use in a semiconductor memory cell, having a trench which is formed in a semiconductor substrate, and to a method of fabrication.

### BACKGROUND OF THE INVENTION

Although they may be applied to any trench capacitors, the present invention and the problems on which it is based are explained below with reference to a trench capacitor used in a DRAM memory cell. Such memory cells are used in integrated circuits (ICs), such as random access memories (RAMs), dynamic RAMs (DRAMs), synchronous DRAMs (SDRAMs), static RAMs (SRAMs) and read-only memories (ROMs). Other integrated circuits contain logic apparatuses, such as programmable logic arrays (PLAs), application-specific ICs (ASICs), hybrid logic/memory ICs (embedded DRAMs) or other circuit apparatuses. Normally, a large number of ICs are fabricated in parallel on a semiconductor substrate, such as a silicon wafer. After processing, the wafer is split in order to separate the ICs into a multiplicity of individual chips. The chips are then packaged in final products, for example for use in consumer products, such as computer systems, cellular phones, personal digital assistants (PDAs) and other products. For the purposes of discussion, the invention is described for the formation of a single memory cell.

Integrated circuits (ICs) or chips use capacitors in order to store charge. An example of an IC which uses capacitors to store charges is a memory IC, such as a chip for a dynamic random access read/write memory (DRAM). In this case, the charge state (“0” or “1”) in the capacitor represents one data bit.

A DRAM chip contains a matrix of memory cells which are interconnected in the form of rows and columns. Normally, the row connections are referred to as word lines and the column connections are referred to as bit lines. The reading of data from the memory cells or the writing of data to the memory cells is brought about by activating suitable word lines and bit lines.

Normally, a DRAM memory cell contains a transistor connected to a capacitor. The transistor contains two diffusion regions which are separated by a channel which has a gate arranged above it. Depending on the direction of the flow of current, one diffusion region is called the drain and the other is called the source. The terms “drain” and “source” are used interchangeably for the diffusion regions in this case. The gates are connected to a word line, and one of the diffusion regions is connected to a bit line. The other diffusion region is connected to the capacitor. The application of a suitable voltage to the gate turns on the transistor, allowing a flow of current between the diffusion regions through the channel so as to form a connection between the capacitor and the bit line. Turning off the transistor breaks this connection by interrupting the flow of current through the channel.

The charge stored in the capacitor is reduced over time on account of an inherent leakage current. Before the charge has been reduced to an indeterminate level (below a threshold value), the storage capacitor needs to be refreshed.

The continual effort made toward reducing the size of the memory apparatuses promotes the design of DRAMs having a greater density and a smaller characteristic size, i.e. a smaller memory cell area. To fabricate memory cells which take up a smaller surface area, smaller components, for example capacitors, are used. However, the use of smaller capacitors results in a lower storage capacity, which in turn can adversely affect the operability and usability of the memory apparatus. By way of example, sense amplifiers require a sufficient signal level for the purpose of reliably reading the information in the memory cells. The ratio of the storage capacity to the bit line capacity is crucial when determining the signal level. If the storage capacity becomes too low, this ratio may be too small to produce an adequate signal. Similarly, a lower storage capacity requires a higher refresh rate.

A type of capacitor which is normally used in DRAMs is a trench capacitor. A trench capacitor has a three-dimensional structure which is produced in the silicon substrate. An increase in the volume or in the capacitance of the trench capacitor can be achieved by etching deeper into the substrate. In this case, the increase in the capacitance of the trench capacitor does not bring about an increase in the size of the surface taken up by the memory cell.

An ordinary trench capacitor contains a trench etched into the substrate. This trench is typically filled with p⁺- or n⁺-doped polysilicon which serves as a capacitor electrode (also referred to as a storage capacitor). The second capacitor electrode is the substrate or a “buried plate”. A capacitor dielectric which contains nitride, for example, is normally used to insulate the two capacitor electrodes.

In the upper region of the trench, a dielectric collar (preferably an oxide region) is produced in order to prevent a leakage current or to insulate the upper part of the capacitor.

The capacitor dielectric is normally removed in the upper region of the trench, where the collar will be formed, before the collar is formed, since this upper part of the capacitor dielectric is a hindrance to subsequent process steps.

In order to increase the storage density for future generations of memory technology further, the feature size is reduced from generation to generation.

As the features become smaller and smaller, the supply resistance of the upper trench capacitor electrode increases to an ever greater extent. As a result of the increasing supply resistance, the access time (RC delay) increases. For this reason, it is necessary to reduce the electrode resistance.

To date, attempts have first been made to increase the doping concentration of the polysilicon which is normally used. Secondly, it has been proposed that the doped polysilicon be replaced by metals having a lower specific resistance. A crucial prerequisite for the suitability of such metals is very high thermal stability, particularly in contact with silicon. Metals proposed to date come from the following classes of materials:
a) elementary metals, such as tungsten, ruthenium, . . .
b) metal nitrides, such as TiN, TaN, . . .
c) metal suicides, such as WSi, TiSi, . . .
d) metal carbides, such as WC, TaC, . . .
e) ternary metals, such as TiSiN, TiAln, . . .
f) conductive metal oxides, such as RuO₂, IrO₂, . . .

Although elementary metals have a very low electrical resistance, for example the specific resistance of ruthenium is <20 μohm cm, they do not have the required thermal stability. Other materials, such as those mentioned under items b) to f), have very good thermal stability but have much higher electrical resistance values (e.g. TiN: approx. 200 μohm cm).

### SUMMARY OF THE INVENTION

The present invention relates to a trench capacitor, particularly for use in a semiconductor memory cell, having a trench which is formed in a semiconductor substrate; a first and second conductive capacitor plate which is situated in a dielectric layer, which is situated between the first and second capacitor plates, as capacitor dielectric; an insulating collar in the upper region of the trench; and a conductive filling material filling the trench, and to an appropriate method of fabrication.

The present invention therefore provides an improved trench capacitor having an insulating collar which has a lower electrode resistance and is nevertheless thermally stable.

One advantage of the present invention is that the electrode resistance can be reduced without increasing the complexity of production. By using low-resistance metal electrodes, the parasitic capacitance of the space-charge zone can be eliminated.

Special metal electrode materials which are proposed are materials from the class including metal borides, metal phosphides and metal antimonides. Specifically, the borides, phosphides and antimonides of the transition metals from the secondary groups IV, V and VI of the periodic table are proposed (particularly titanium, zirconium, hafnium, vanadium, niobium, tantalum, chromium, molybdenum, tungsten).

These are distinguished not only by mechanical hardness and chemical resistance, but also by high thermal stability (melting points in some cases greater than 2500° C.), even in contact with silicon, and excellent metal conductivity (specific resistance <20 μohm cm).

The special metal electrode materials may be deposited, inter alia, using CVD methods without difficulty in features with very high aspect ratios with very good edge coverage. In particular, these electrode materials may therefore be combined very well using methods for enlarging the surface, for example wet bottle, roughing up the surface in the trench etc.

In line with one preferred embodiment, the material is selected from the following group: TiB₂, ZrB₂, HfB₂, TiP, ZrP, HfP, TiSb₂, ZrSb₂, HfSb₂.

In line with another preferred embodiment, the first conductive capacitor plate has a layer of increased doping in the semiconductor substrate in the lower region of the trench, and the second conductive capacitor plate has a filling for the trench made of the material.

In line with another preferred embodiment, the second conductive capacitor plate has a first film, provided on the dielectric layer in the interior of the trench, made of the material.

In line with another preferred embodiment, the first conductive capacitor plate has a second film, provided between the dielectric layer and the semiconductor substrate, made of the material.

In line with another preferred embodiment, the second conductive capacitor plate has a third film, provided on the dielectric layer in the interior of the trench, made of the material.

In line with another preferred embodiment, the dielectric layer and the second and third films are routed into the region of the insulating collar.

In line with another preferred embodiment, the trench has a lower widened region.

In line with another preferred embodiment, the layer is fabricated by providing a filling in the trench made of the material and subsequently etching back the filling.

In line with another preferred embodiment, the layer is fabricated by depositing a film in the trench made of the material and subsequently etching back the film.

In line with another preferred embodiment, the layer is fabricated by depositing a film made of TiN in the trench, annealing the film made of TiN in a phosphorous atmosphere, particularly in phosphine, in order to convert a layer of the film into TiP, and subsequently etching back the film.

### BRIEF DESCRIPTION OF THE DRAWINGS

Exemplary embodiments of the present invention are illustrated in the drawings and are explained in more detail in the description below.

In the figures:

FIGS. 1a-m show the method according to the invention for fabricating a first exemplary embodiment of the inventive trench capacitor.

FIGS. 2a-e show the method according to the invention for fabricating a second exemplary embodiment of the inventive trench capacitor.

FIGS. 3a-g show the method according to the invention for fabricating a third exemplary embodiment of the inventive trench capacitor.

In the figures, identical reference symbols denote components which are the same or have the same function.

### DETAILED DESCRIPTION OF THE INVENTION

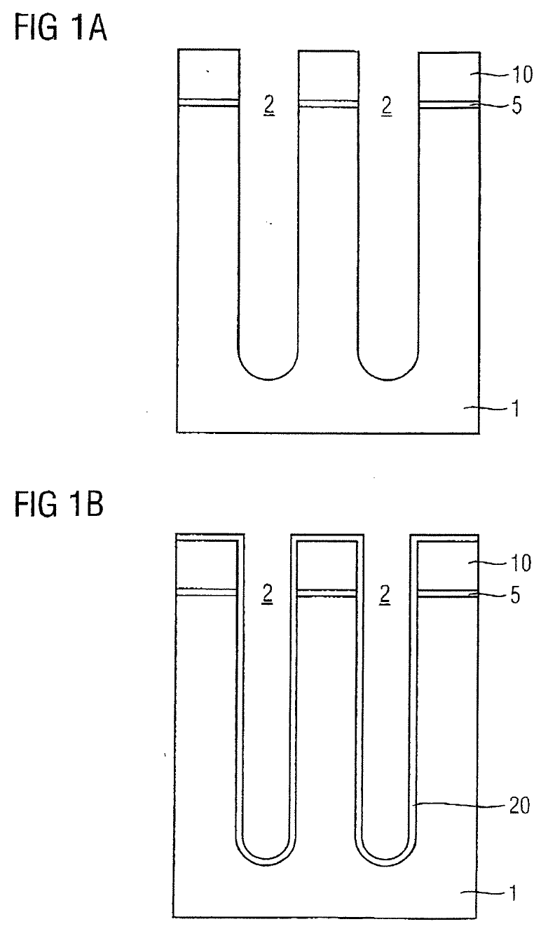

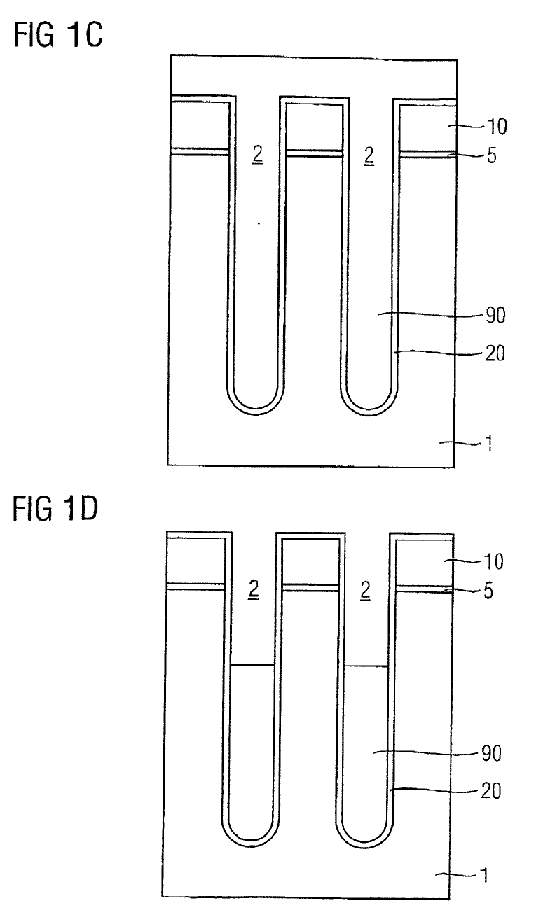

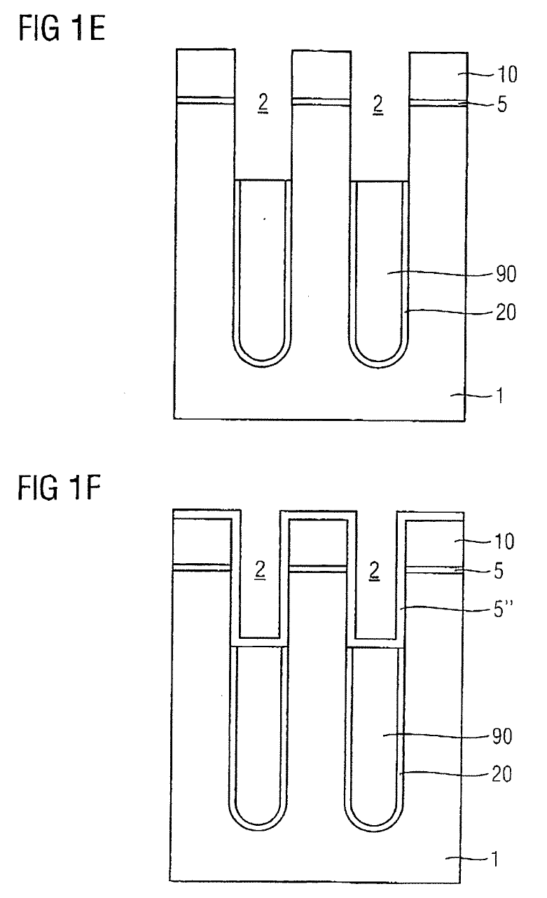

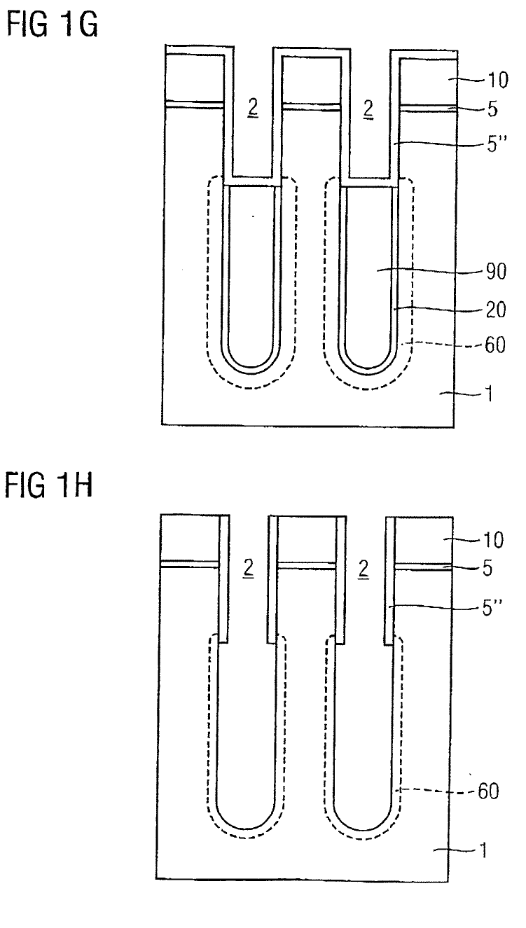

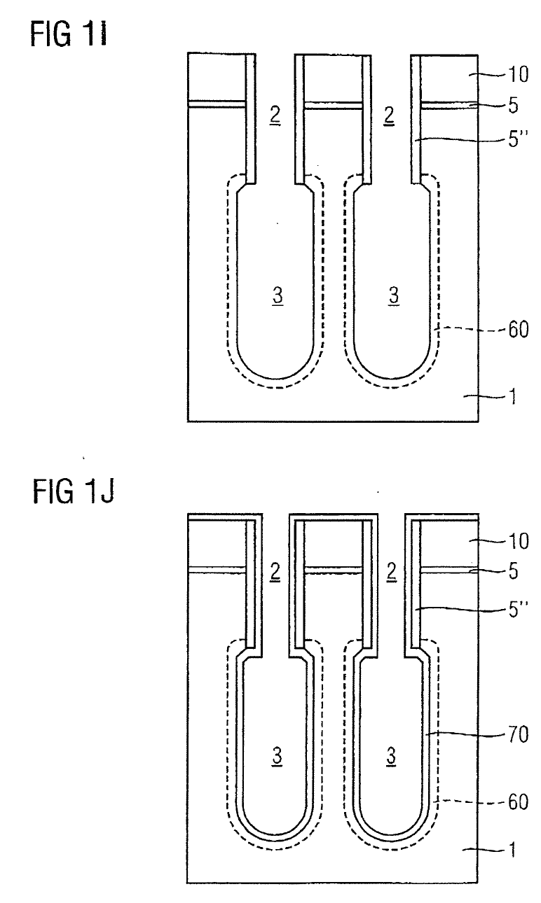

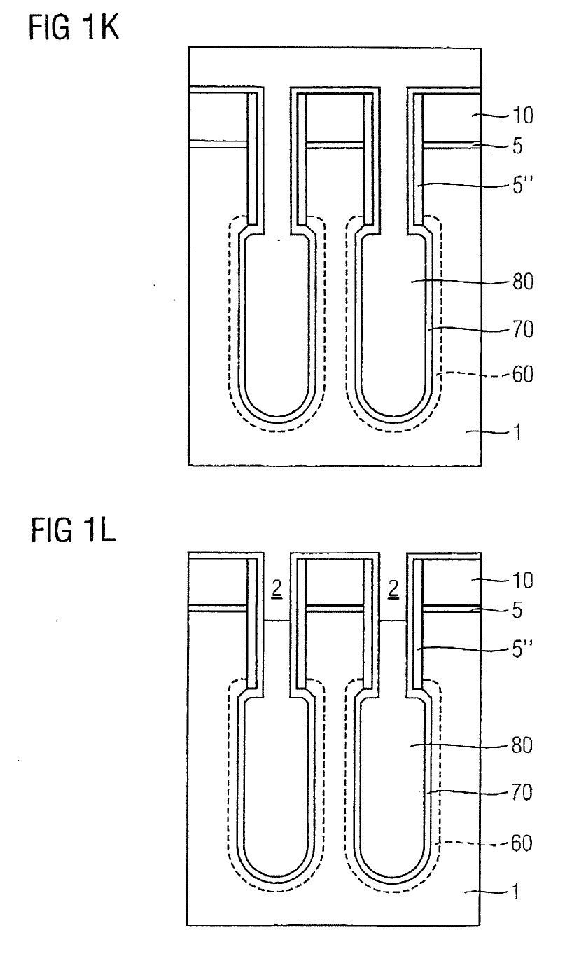

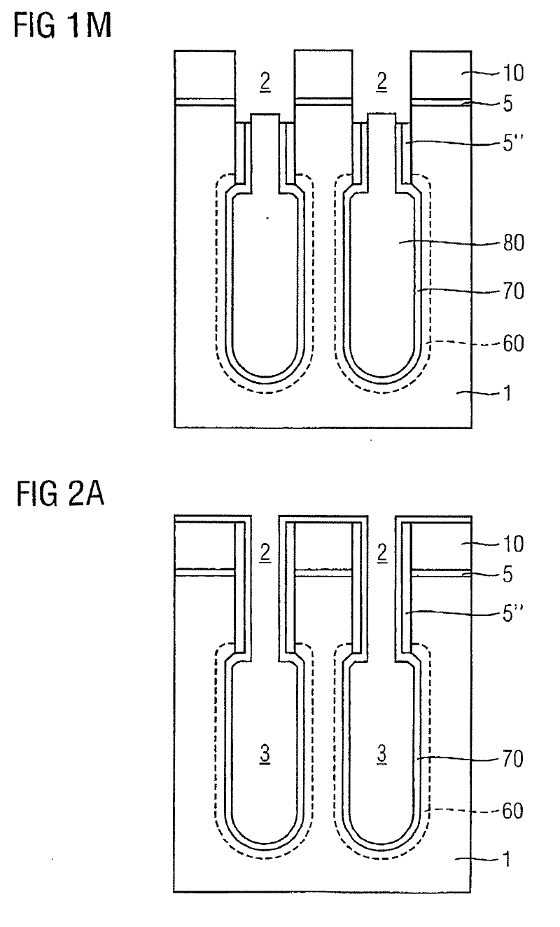

FIGS. 1a-m show the method according to the invention for fabricating a first exemplary embodiment of the inventive trench capacitor.

In the case of the present first embodiment, a pad oxide layer 5 and a padnitride layer 10 are first of all deposited on a silicon substrate 1, as shown in FIG. 1a. Next, a further oxide layer (not shown) is deposited and these layers are then patterned using a photoresist mask (likewise not shown) and an appropriate etching method to form a “hard mask”. Using this hard mask, trenches 2 with a typical depth of approximately 1-10 μm are etched into the silicon substrate 1. The topmost oxide layer is then removed in order to arrive at the state shown in FIG. 1a.

In a subsequent process step, as FIG. 1b shows, arsenic silicate glass (ASG) 20 is deposited on the resultant feature, so that the ASG 20 fully lines the trenches 2, in particular.

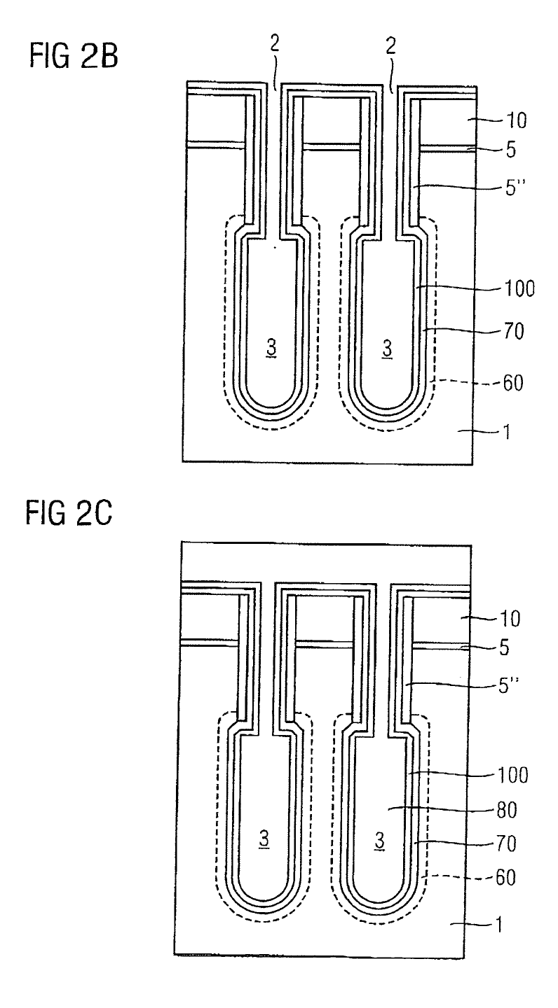

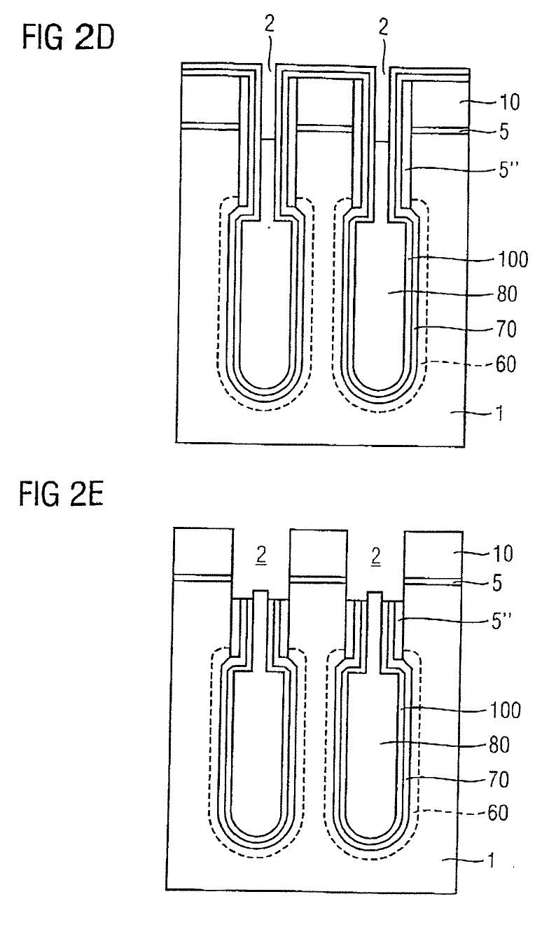

As FIG. 1c shows, the deposition of the ASG layer 20 is followed by the resultant feature being filled with undoped polycrystalline silicon 90, which is subsequently removed by isotropic dry-chemical etching in the upper region of the trench in order to achieve the state shown in FIG. 2d.

In a further process step, the ASG 20 is removed by a wet-chemical isotropic etching step in the upper exposed trench region, as shown in FIG. 1e. The collar oxide 5″ is deposited over the whole area, as shown in FIG. 1f.

In the next process step, shown in FIG. 1g, arsenic is diffused out of the ASG 20 into the surrounding region of the silicon substrate 1 in order to form the buried plate 60.

Next, the collar oxide 5″ is anisotropically etched in order to remove it from the surface of the resultant feature, which means that it now remains on the side walls in the upper region of the trenches 2. The polysilicon 90 is then removed by isotropic etching, and in a further step the ASG 20 is likewise removed by an isotropic wet-chemical etching process. This results in the state shown in FIG. 1h.

In a further process step, a widened lower trench region 3 is now formed by an etching process which is known in the prior art, or a wet bottle etching process, which results in the feature shown in FIG. 1i.

In the next process step, shown in FIG. 1j, the dielectric 70 with a high dielectric constant is deposited using an ALD or ALCVD method or CVD method. Suitable materials for the dielectric 70 with a high dielectric constant are, by way of example: Al₂O₃, Ta₂O₅, ZrO₂, HfO₂, Y₂O₃, La₂O₃, TiO₂; Al—Ta—O, Al—Zr—O, Al—Hf—O, Al—La—O, Al—Ti—O, Zr—Y—O, Zr—Si—O, Hf—Si—O, Si—O—N, Ta—O—N and similar materials. It is also possible to use rare earth oxides, rare earth mixed oxides with two or more rare earth metals, metal silicon oxynitrides or metal aluminum oxynitride as dielectric 70.

This deposition can be performed with a very high level of uniformity and conformality using the ALD or ALCVD or CVD method.

As can be seen in FIG. 1j, the deposition method used means that the feature is covered very uniformly by the dielectric 70 with a high dielectric constant, which ensures that no unwanted leakage currents arise at critical points, such as edges or areas of greater curvature.

In the next process step, a filling 80 made of a special metal electrode material is deposited by means of CVD, which results in the feature shown in FIG. 1k.

The metal electrode material used for the filling 80 in this embodiment is generally a material from the class containing metal borides, metal phosphides and metal antimonides. Specifically, the borides, phosphides and antimonides of the transition metals from the secondary groups IV, V and VI of the periodic table are proposed (particularly titanium, zirconium, hafnium, vanadium, niobium, tantalum, chromium, molybdenum, tungsten).

These are distinguished not only by mechanical hardness and chemical resistance but also by high thermal stability (melting points in some cases greater than 2500° C.), even in contact with silicon, and excellent metal conductivity (specific resistance <20 μΩcm).

One specific example proposed for this embodiment is TiB₂.

By etching back the metal electrode filling 80 with H₂O₂, the feature shown in FIG. 11 is obtained.

One alternative would be ZrB₂, which can easily be etched back with HNO₃/HF.

Finally, the dielectric 70 with a high dielectric constant and the collar oxide 5″ are subjected to wet-chemical isotropic etching in the upper region of the trenches 2 in order to obtain the feature shown in FIG. 1m.

FIGS. 2a-e show the method steps according to the invention for fabricating a second exemplary embodiment of the inventive trench capacitor.

The state shown in FIG. 2a corresponds to the state shown in FIG. 1j, whose previous history has been explained in detail above in connection with the second embodiment.

In line with FIG. 2b, a film 100 made of a special metal electrode material is subsequently provided, specifically a TiN/TiP stack. This means that there is the advantage of the thermal stability of TiN and the very good conductivity of TiP, for example.

In this connection, R. Leutenecker et al. describe, in “Microelectronic Engineering”, 37/38, pages 397 ff., 1997, deposition of TiN using a CVD method and subsequent annealing of the TiN layer in phosphine at 450° C., forming an upper layer made of titanium phosphide.

In the next process step, arsenic-doped polysilicon 80 or polysilicon germanium is deposited, which results in the feature shown in FIG. 2c.

By etching back the polysilicon or polysilicon germanium 80, the feature shown in FIG. 2d is obtained.

Finally, the metal electrode film 100, the dielectric 70 with a high dielectric constant and the collar oxide 5″ are subject to wet-chemical isotropic etching in the upper region of the trenches 2 in order to obtain the feature shown in FIG. 2e.

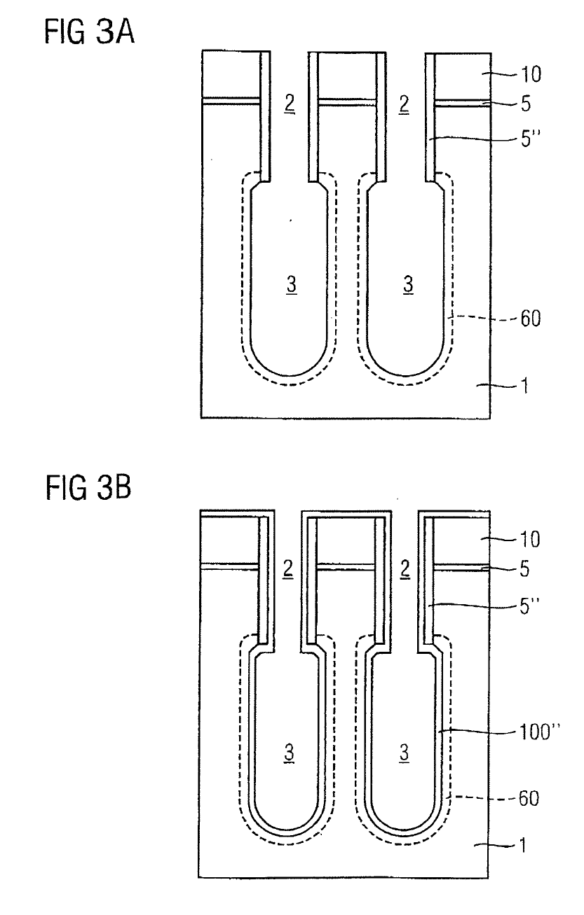

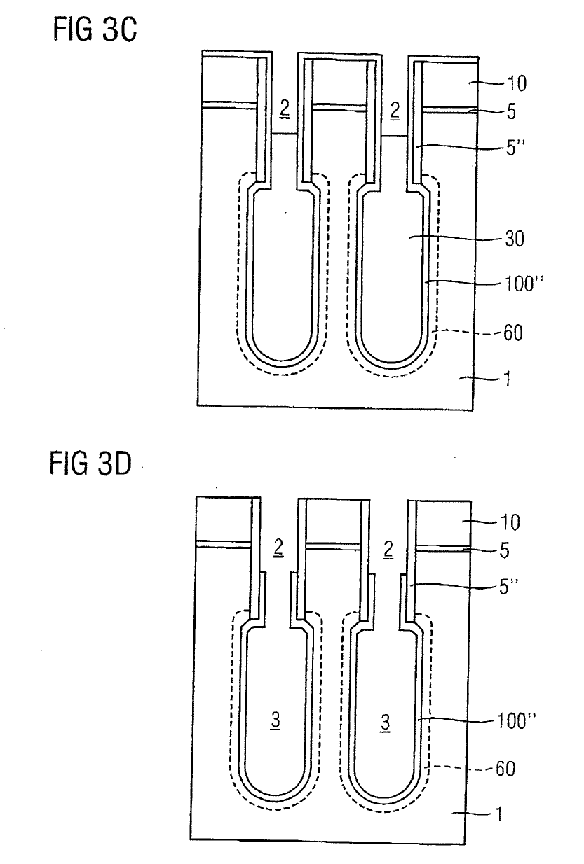

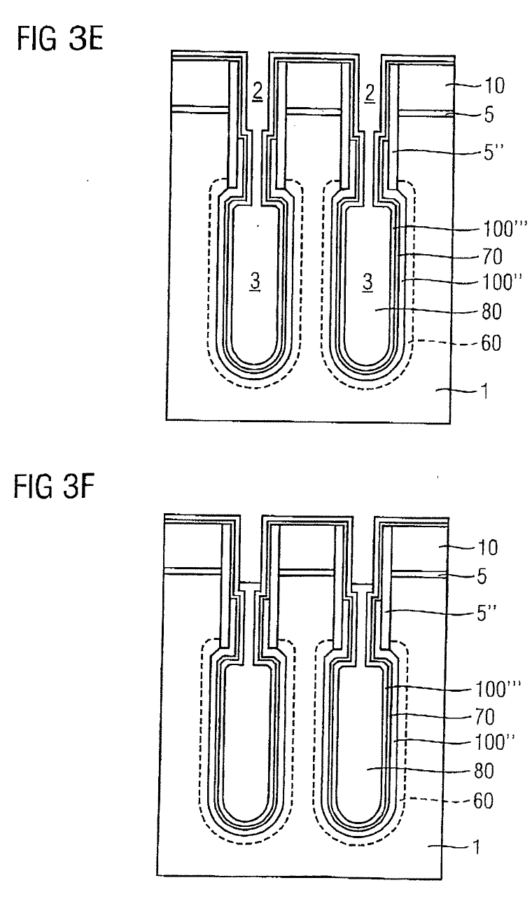

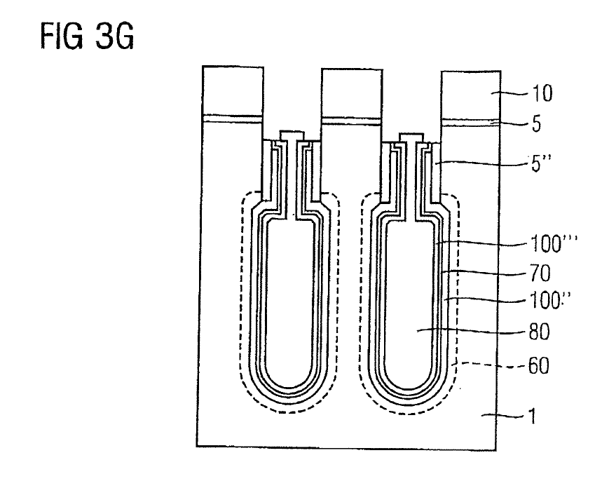

FIGS. 3a-g show the method steps according to the invention for fabricating a third exemplary embodiment of the inventive trench capacitor.

The state shown in FIG. 3a corresponds to the state shown in FIG. 1i, whose previous history has already been explained in detail in connection with the first embodiment above.

To achieve the state shown in FIG. 3b, a film 100″ made of a special metal electrode material, as specified in the first exemplary embodiment above, is deposited on the resultant feature using a CVD method.

The feature is filled with photoresist 30, and the photoresist 30 is etched back in order to obtain the feature shown in FIG. 3c. The metal electrode layer 100″ is then etched back in the exposed region, and the photoresist 30 is subsequently removed. This is shown in FIG. 3d.

Next, in line with FIG. 3e, the special dielectric 70 with a high dielectric constant and also a further film 100′″ made of a special metal electrode material, as specified in the first exemplary embodiment above, are deposited on the resultant feature using a CVD method.

Arsenic-doped polysilicon 80 or polysilicon germanium are then deposited and etched back. This results in the feature shown in FIG. 3f.

Finally, the two metal electrode layers 100″ and 100′″, the dielectric layer 70 and the collar oxide 5″ are etched back in the upper region in order to obtain the feature shown in FIG. 3g.

Although the present invention has been described above using a preferred exemplary embodiment, it is not limited thereto but rather can be modified in a wide variety of ways.

In particular, the materials indicated are merely exemplary and can be replaced by other materials with suitable properties. The same applies to the etching processes and deposition processes mentioned.

Further examples of the metal electrode material are TiB₂, ZrB₂, HfB₂, TiP, ZrP, HfP, TiSb₂, ZrSb₂, HfSb₂, in particular.

### List of Reference Symbols

1 Silicon substrate
2 Trench
3 Widened region
5 Pad oxide
5″ Collar oxide
10 Padnitride
20 ASG
30 Photoresist
60 Buried plate
70 Dielectric
80 Doped polysilicon
90 Undoped polysilicon
100, 100″, 100″ Metal electrode layer

1. A trench capacitor for use in a semiconductor memory cell, comprising:
a trench which is formed in a semiconductor substrate;
a first conductive capacitor plate which is situated in and/or next to the trench;
a second conductive capacitor plate which is situated in the trench;
a dielectric layer, which is situated between the first and second capacitor plates, as capacitor dielectric; and
an insulating collar in an upper region of the trench; wherein
at least one layer of the first first conductive capacitor plate and the second conductive capacitor plate is made of a material from the group including metal borides, metal phosphides and metal antimonides of transition metals from secondary groups IV, V and VI of the periodic table.

2. The trench capacitor according to claim 1, wherein the material is selected from the following group: TiB₂, ZrB₂, HfB₂, TiP, ZrP, HfP, TiSb₂, ZrSb₂, HfSb₂.

3. The trench capacitor according to claim 1, wherein the first conductive capacitor plate has a layer of increased doping in the semiconductor substrate in the lower region of the trench, and the second conductive capacitor plate has a filling for the trench made of the material.

4. The trench capacitor according to claim 1, wherein the second conductive capacitor plate has a first film, provided on the dielectric layer in the interior of the trench, made of the material.

5. The trench capacitor according to claim 1, wherein the first conductive capacitor plate has a second film, provided between the dielectric layer and the semiconductor substrate, made of the material.

6. The trench capacitor according to claim 5, wherein the second conductive capacitor plate has a third film, provided on the dielectric layer in the interior of the trench, made of the material.

7. The trench capacitor according to claim 6, wherein the dielectric layer and the second and third films are routed into the region of the insulating collar.

8. The trench capacitor according to claim 1, wherein the trench has a lower widened region.

9. A method for fabricating a trench capacitor for use in a semiconductor memory cell, comprising:
providing a trench in a semiconductor substrate;
providing a first conductive capacitor plate which is situated in and/or next to the trench;
providing a second conductive capacitor plate which is situated in the trench;
providing a dielectric layer which is situated between the first and second capacitor plates as capacitor dielectric; and
providing an insulating collar in an upper region of the trench; wherein
at least one layer of the first first conductive capacitor plate and the second conductive capacitor plate is fabricated from a material from a group including metal borides, metal phosphides and metal antimonides of the transition metals from secondary groups IV, V and VI of the periodic table.

10. The method according to claim 9, wherein the layer is fabricated by providing a filling in the trench made of the material and subsequently etching back the filling.

11. The method according to claim 9, wherein the layer is fabricated by depositing a film in the trench made of the material and subsequently etching back the film.

12. The method according to claim 9, wherein the layer is fabricated by depositing a film made of TiN in the trench, annealing the film made of TiN in a phosphorous atmosphere to convert a layer of the film into TIP, and subsequently etching back the film.
